(19) United States
(12) Patent Application Publication
(10) Pub. No.: US 2008/0257401 A1
(43) Pub. Date: Oct. 23, 2008

(54) Photovoltaic module and method for production thereof

(75) Inventors: Hubert Lauvray, Saint Clair du Rhone (FR); Roland Einhaus, Bourgoin Jallieu (FR); Guy Baret, Voiron (FR); Klaus Bamberg, Lyon (FR)

Correspondence Address: OLIFF & BERRIDGE, PLC, P.O. BOX 320850, ALEXANDRIA, VA, 22320-4850, US

(73) Assignee: APOLLON SOLAR, Paris (FR)

(21) Appl. No.: 12/010,719

(22) Filed: Jan. 29, 2008

Related U.S. Application Data
(62) Division of application No. 10/551,554, filed on Oct. 3, 2005, now abandoned.

(30) Foreign Application Priority Data
Apr. 16, 2003 (FR) 03/04729
Nov. 18, 2003 (FR) 03/13489

(51) Int. Cl. H01L 31/042

(52) U.S. Cl. 136/251

(57) ABSTRACT

The photovoltaic module comprises front and rear plates. An organic seal is arranged between the plates and delineates a tight internal volume, kept at a pressure lower than atmospheric pressure, wherein the photovoltaic cells are arranged. The seal is an organic seal, for example of thermoplastic nature, for example of the polybutylene family. The production method comprises formation of a negative pressure by suction. The method can comprise sweeping by neutral gases, establishment of the negative pressure and sealing by compression. The method can also comprise partial sealing of the module so as to leave two openings in the seal, sweeping of the internal volume by neutral gases by means of the two openings, establishment of the negative pressure and closing of the openings.

This is a Division of application Ser. No. 10/551,554 filed Oct. 3, 2005, which is a National Stage of PCT Application No. PCT/FR04/000925 filed Apr. 14, 2004. The disclosure of the prior applications is hereby incorporated by reference herein in its entirety.

### BACKGROUND OF THE INVENTION

The invention relates to a photovoltaic module comprising an assembly of photovoltaic cells arranged side by side between front and rear plates, and a seal arranged between the plates and delineating a tight internal volume, kept at a pressure lower than atmospheric pressure, wherein the photovoltaic cells are arranged.

### STATE OF THE ART

Conventionally, to fabricate a photovoltaic module, photovoltaic cells are covered with a network of electrodes and are connected to one another by soldering of metal strips. The assembly thus formed is then placed between two sheets of polymer themselves held between two glass substrates. This assembly is then heated to about 120° C. to soften the polymer greatly, to make it airtight and transparent and to ensure the mechanical consistency of the module. However tightness, especially against penetration by humidity, is often not achieved in the long term.

This type of production method consumes a large amount of tin-, lead- and zinc-based soldering paste, which is very expensive. The soldering itself is an expensive, mechanically complicated operation, requiring the cell to be turned and involving non-negligible risks of breaking the cell.

To achieve tightness of the module, a non-mineral seal can be deposited at the periphery of all of the cells or the space remaining between the glass substrates is filled with an organic resin.

The document WO03/038,911 describes a method for production of a photovoltaic module comprising assembly of photovoltaic cells arranged side by side between front and rear plates. A mineral seal, arranged between the plates, delineates a tight internal volume wherein all the cells are arranged. The sealing operation takes place at a temperature comprised between 380° C. and 480° C. for a time of less than 30 minutes. During sealing, the seal material softens greatly and makes the internal volume of the seal tight with respect to the outside, which prevents any water from entering the module throughout the lifetime of the module. The pressure of the internal volume is about one atmosphere at sealing temperature. The final pressure, after cooling to ambient temperature, is lower, in the region of 400 millibars. A negative pressure with respect to the outside therefore automatically forms inside the assembly and results in a force being applied by the front and rear plates on the cells. This force ensures a contact between the cells and connecting conductors deposited on the front and rear plates without soldering having to be performed between the cells and the connecting conductors. However, applying a temperature of about 400° C. is liable to impair the quality of the photovoltaic cells currently available on the market.

A photovoltaic cell can be formed on a bulk silicon substrate cut into wafers with a thickness of a few hundred microns. The substrate can be formed by monocrystalline silicon, polycrystalline silicon or semiconducting layers deposited on a glass or ceramic substrate. It has at its surface a network of narrow electrodes, generally made of silver or aluminium, designed to drain the current to one or more main electrodes having a width of 1 to a few millimeters, also made of silver or aluminium.

In a known photovoltaic module, rear connecting conductors associated to a first cell are connected to the front connecting conductors associated to a second, adjacent cell. If the module comprises more than two cells, the rear connecting conductors of the second cell are then connected to the front connecting conductors of the next cell, all the cells thus being electrically connected in series. In practice, a rear connecting conductor of a cell and the front connecting conductor associated to the adjacent cell can be formed by one and the same interconnecting conductor. The connecting conductors of the end cells act as external connectors.

An assembly of photovoltaic cells in matrix form can comprise transverse connecting conductors connecting the cells electrically in parallel. Typically the transverse connecting conductors, formed by a copper core and a superficial deposit of a tin-lead alloy, are soldered with a tin-lead alloy onto connecting zones of the cell. The connecting conductors can also be achieved by depositing a silver paste on a support plate of the module according to the required pattern, followed by annealing at high temperature.

In the document DE-A-4,128,766, the front and rear connecting conductors are formed on the internal face of the front and rear glass substrates facing the location of each of the cells. The connecting conductors are then soldered onto the cells and onto the interconnecting elements designed to connect the cells in series. The space remaining between the glass substrates is then filled with an organic resin.

Moreover, in certain known cells (U.S. Pat. No. 6,384,317), the positive and negative poles of the cell are disposed on one of the faces of the latter, in particular on the rear face thereof.

Soldering the connecting conductors and assembling the cells constitutes a handicap as they are long and expensive operations that are able to break the cells and result in a high production cost.

### OBJECT OF THE INVENTION

The object of the invention is to remedy these shortcomings and, in particular, to achieve a module presenting a good long term tightness, and to simplify the production method of a photovoltaic module so that production thereof can preferably be performed at ambient temperature, while at the same time reducing the production costs.

According to the invention, this object is achieved by the appended claims and, in particular, by the fact that the seal is a flexible organic seal.

### BRIEF DESCRIPTION OF THE DRAWINGS

Other advantages and features will become more clearly apparent from the following description of particular embodiments of the invention given as non-restrictive examples only and represented in the accompanying drawings, in which:

FIGS. 1 and 2 illustrate the assembly steps of a particular embodiment of a method for production of a photovoltaic module according to the invention.

FIGS. 3 and 4 illustrate, in cross-section along the line A-A, a particular embodiment of the suction step of a method for production of a photovoltaic module according to FIG. 2.

FIGS. 5 and 6 represent two particular embodiments of a photovoltaic module according to the invention.

FIGS. 7 and 8 illustrate two particular embodiments of a method for production of a photovoltaic module according to the invention.

FIGS. 9 and 10 represent a particular embodiment of a photovoltaic module according to the invention respectively in cross-section along the line B-B and in bottom view.

FIGS. 11 and 12 represent various particular embodiments of interconnecting conductors of a photovoltaic module according to the invention.

### DESCRIPTION OF PARTICULAR EMBODIMENTS

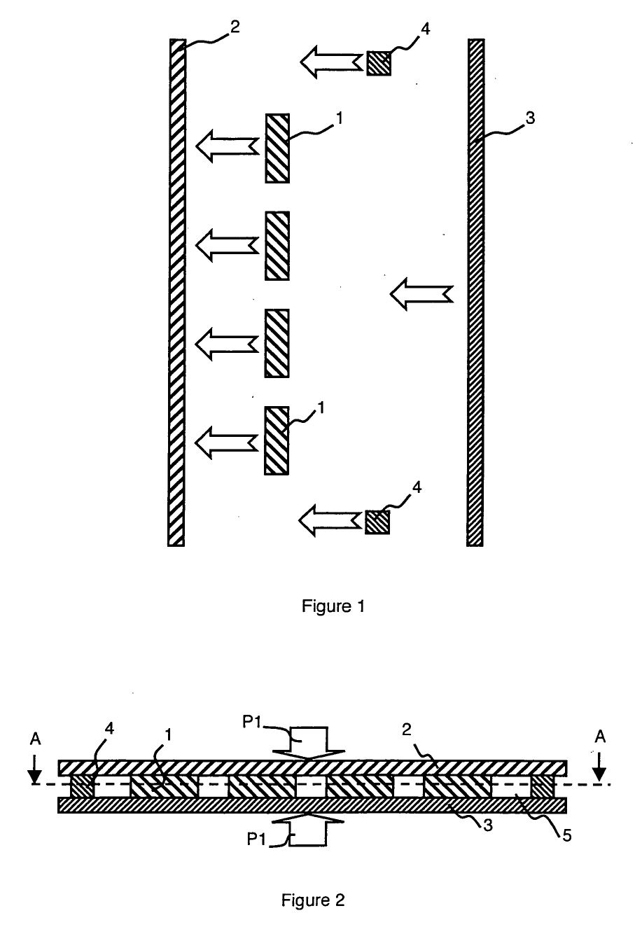

FIG. 1 represents assembly of photovoltaic cells 1 arranged side by side between a front plate 2 and a rear plate 3 and of an organic seal 4. For assembly, the plates 2 and 3 and the photovoltaic cells 1 are kept parallel to one another. To secure the photovoltaic cells 1 during assembly, the latter can be pre-fixed, as can the corresponding electrical interconnecting conductors, before assembly of the plates 2 and 3, onto one of the plates, for example on the rear plate 3. They can for example be pre-stuck by means of a solvent-free organic glue, for example by a derivative of the polyvinyl family. The glue can be constituted by the same material as the organic seal 4, for example by a polybutylene derivative. Then the organic seal 4 can be deposited on one of the plates 2 and 3, for example on the front plate 2, at the periphery of the set of photovoltaic cells 1. Then the front plate 2 and rear plate 3 are sealed by means of the organic seal 4, which can be of thermoplastic nature, for example of the polybutylene family. The organic seal 4 can be made of any organic material able to provide an efficient barrier against humidity and gases, in particular oxygen. The tight internal volume 5 is filled with a neutral gas. The neutral gas can be constituted by any pure or mixed gas compatible with the materials of the elements arranged inside the tight volume, for example argon. The gas concentration, in particular the argon concentration, can be determined by spectral analysis, which enables the atmosphere and the gas composition inside the tight internal volume 5 to be controlled.

In the course of assembly, as represented in FIG. 2, the module assembly is preferably compressed by applying a pressure P1 on the plates 2 and 3. Thus, the organic seal 4 confines a tight internal volume 5 inside which all the photovoltaic cells 1 are arranged. The material of the organic seal 4 is preferably of the polybutylene family, without a solvent, for example poly-iso-butylene. After it has been fitted and compressed, the polybutylene seal remains flexible and its colour, initially mat black, changes to glossy black, at the interface with the plates 2 and 3, which enables the tightness to be checked if required. The mechanical characteristics of the seal remain unchanged although the seal keeps a certain flexibility. The module compression step thus enables the thickness of the module to be controlled.

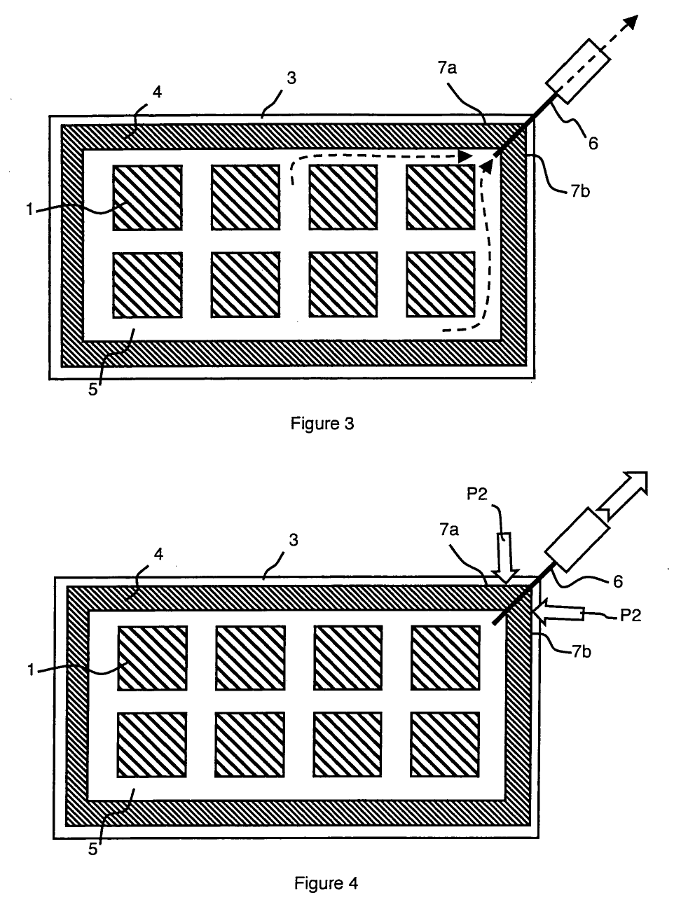

According to the invention, the negative pressure is formed by suction in order to ensure a sufficient contact pressure to achieve the electrical conduction necessary for satisfactory operation of the module without soldering of the interconnection contacts between cells. In a first particular embodiment of the production method, represented in FIGS. 3 and 4, suction is performed after sealing of the module. Suction enables a negative pressure of up to 0.5 bar to be created in the tight internal volume 5. Suction (represented schematically by dashed arrows) is for example performed by means of a perforating tool, for example by means of a syringe 6 passing through the organic seal 4 and connected to an external suction device (not represented). The perforating tool is dimensioned so that, when it is removed, the tightness is not impaired. In FIG. 3, the syringe 6 is inserted into the organic seal 4 close to a corner of the module. The residual flexibility of the organic seal means that the small opening via which the syringe enters is automatically reclosed when the syringe is removed. As represented in FIG. 4, when the syringe 6 is removed, applying a pressure P2 on two perpendicular faces 7a and 7b of the seal on each side of the opening via which the syringe enters enables this opening to be reclosed and ensures tightness of the seal. The method preferably comprises, before the negative pressure is created, a sweeping step by neutral gases, which may be performed by means of two syringes, a first syringe performing suction and a second syringe simultaneously supplying the neutral gases.

After the organic seal 4 has been implemented, the tight internal volume 5 is kept at a pressure substantially lower than atmospheric pressure, which results in a force being applied by the front plate 2 and rear plate 3 on the photovoltaic cells 1. This force ensures a contact between the cells and connecting conductors performing the electrical connections between the cells, without it being necessary to deposit any solder between the cells and the connecting conductors. The material forming the connecting conductors can be copper-based, a copper alloy or any other high-conductivity metallic material ensuring a good contact with the photovoltaic cells 1 under the action of the negative pressure force.

The tightness of the organic seal 4 is obtained after compression of the front and rear plates, with the organic seal present at the periphery of the whole of the module. The thickness of the seal, determined by the quantity of organic material deposited and by the compression force when sealing is performed, then remains constant. As the method is performed at ambient temperature, it is compatible with all photovoltaic cells.

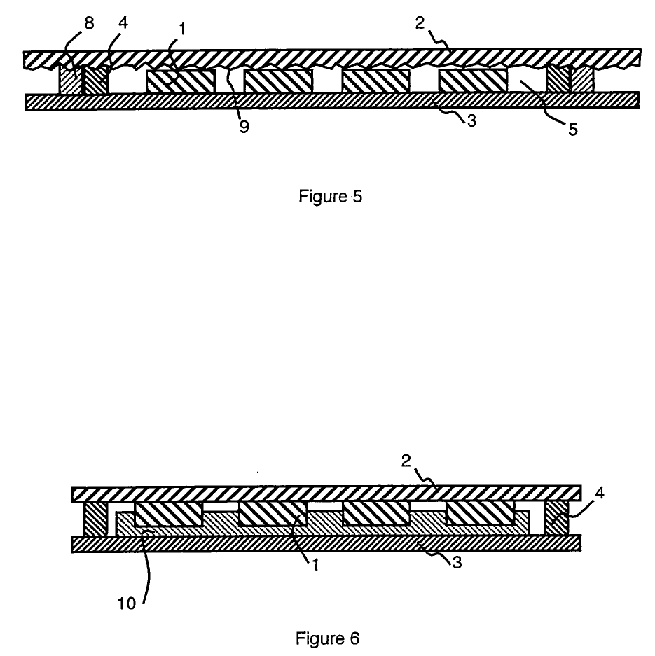

The organic seal 4, in particular when it is made of polybutylene, keeps a certain elasticity after implementation. As represented in FIG. 5, a strengthening system 8 may be arranged around the seal 4 to improve the solidity of the module.

The front 2 and rear 3 plate can both be glass plates, for example made of soda-lime glass with a thickness of 1.6 to 6 mm, a typical value being from 3 to 4 mm for the front plate 2 and from 2 to 4 mm for the rear plate 3. The glass is advantageously a clear or flint glass, i.e. containing little iron, as the optical transmission of such a glass is very good. The glass can also have undergone thermal hardening to increase its mechanical strength. However, the front plate 2 of the photovoltaic module is preferably made of glass, whereas the rear plate 3 is formed by a rigid sheet, insulating at least at the surface, made of plastic or metal, for example aluminium or surface-treated stainless steel so as not to be conducting at the surface. Such a sheet enables the photovoltaic cells to be protected while considerably reducing the weight (up to 2 times).

The method can, in addition, comprise a chemical etching step of the glass front plate, for example alkaline etching, performed before the module is assembled, so as to roughen the internal face 9 of the front glass plate, i.e. the face facing the photovoltaic cells 1, as represented in FIG. 5. Thus, the radiation reflected by the photovoltaic cells 1 is partly recovered by multiple reflections on the different zones of the surface of the front plate 2. The treatment can be performed by anisotropic etching of the glass, the external face of the front plate 2 being protected, so as to give the internal face 9 of the front plate 2 a texture. This technique enables an improvement of the efficiency of the photovoltaic module to be obtained. This texturing can also be performed by hardening the glass, after protecting the external face of the glass, for example by chemical etching.

The photovoltaic module represented in FIG. 6 comprises, in addition, between the photovoltaic cells 1 and the rear plate 3 and/or between the photovoltaic cells 1, a substance 10 designed to absorb the infrared and ultraviolet radiation and to emit a radiation in a visible spectral band corresponding substantially to the maximum of the absorption band of the photovoltaic cells. The substance 10 comprises, for example, polymethyl methacrylate (PMMA) and/or a metallic salt and/or a pigment formed by a compound mainly containing mixed oxides of lanthanum-, erbium-, terbium-, neodymium- and praseodymium-based rare earths, alkaline metals or metals belonging to the alkaline earths. These oxides transform the ultraviolet radiation into visible radiation having a wavelength comprised between 550 nm and 650 nm. The efficiency of the photovoltaic module can thus be increased. Absorption of the infrared radiation enables the operating temperature of the photovoltaic cells to be reduced.

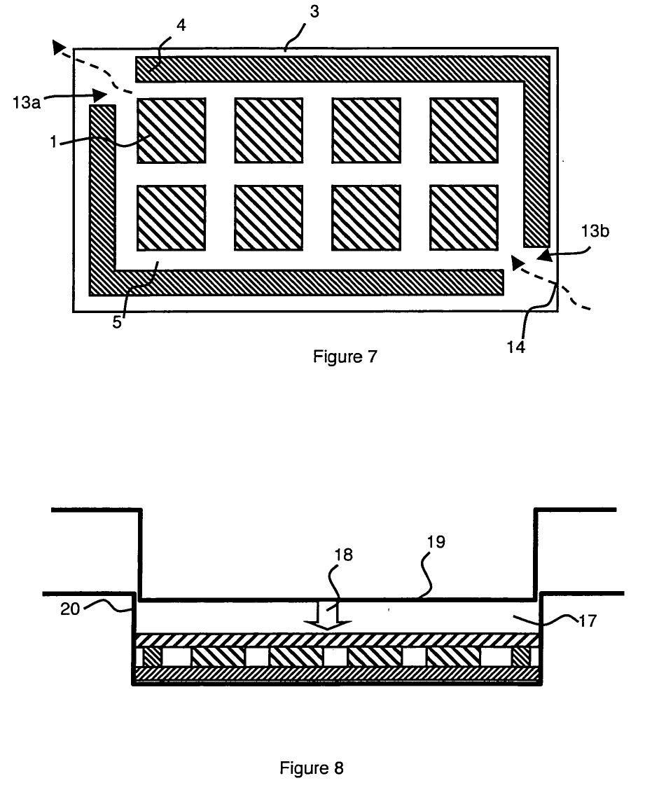

In a second particular embodiment of the production method, represented in FIG. 7, the method successively comprises assembly and partial sealing of the module, so as to leave two openings 13a and 13b in the seal 4, and sweeping by neutral gases, schematically represented by dashed arrows 14, of the internal volume by means of two openings 13a and 13b. The negative pressure is then established by suction by means of the two openings 13a and 13b. After suction, the two openings 13a and 13b are closed without impairing the negative pressure. It is also possible to close one of the openings 13 after sweeping and to perform suction by means of the other opening 13, which is then closed.

In a third particular embodiment of the production method, represented in FIG. 8, the method successively comprises assembly of the module and, in a tight enclosure 17, sweeping by neutral gases and establishment of the negative pressure by suction. Sealing of the front 2 and rear plate 3 is then performed by compression 18 of the seal 4, the front 2 and rear plate 3 being arranged between two preformed parts 19 and 20 also enabling the tight enclosure 17 to be established.

The module according to the invention can be of large dimensions, the glass having a corresponding thickness, without a frame having to be added thereto.

The invention applies to any type of photovoltaic modules, including modules comprising photovoltaic cells 1 each having positive and negative poles arranged on one and the same side of the cell, as described above.

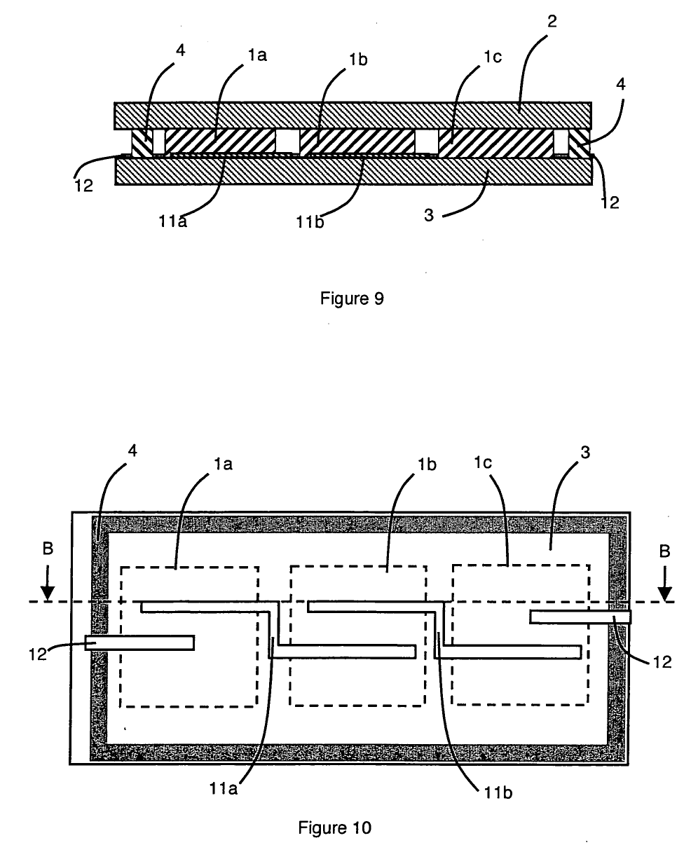

The photovoltaic module represented in FIG. 9 comprises photovoltaic cells 1 arranged side by side between internal faces of the front 2 and rear plate 3. Only three cells 1a, 1b and 1c are represented in FIG. 9 for the sake of clarity. Positive and negative poles of each cell are disposed on the rear face of the latter.

Connection of a positive pole of a cell and a negative pole of the adjacent cell is achieved very simply by means of at least one interconnecting conductor formed by a metal strip, for example by a strip of silver paste, deposited, for example by screening, on the internal face of the rear plate 3 before the cells are fitted in place. It is also possible to perform electrical interconnection of cells by means of metal conductors pre-fixed by a glue onto the rear plate of the module.

In FIGS. 9 and 10, a metal strip 11a, deposited on the rear plate 3, is positioned on a zone joining the locations of the two adjacent cells 1a and 1b, so as to come into contact on the rear face of the cells 1a and 1b, respectively with the positive pole of the cell 1a and with the negative pole of the cell 1b. In FIG. 10, the zone presents the shape of a stair. A strip of silver paste 11b, connecting the positive pole of the cell 1b to the negative pole of the cell 1c, is disposed in like manner on the rear plate 3. A network of interconnecting conductors 11 is thus formed on the rear plate 3, before the cells are fitted in place. When the rear face is not optically active, there is no constraint on optical transmission of the rear plate 3 and the pattern of the network of strips of silver paste 11 is chosen such that conduction is maximal. According to a first alternative embodiment, the width of the strips of silver paste 11 is large, each strip of silver paste 11 being able, for example, to have a width comprised between 3 mm and 10 mm, more typically comprised between 3 mm and 5 mm.

When the positive and negative poles of the cells are arranged respectively on the front face and on the rear face, the interconnections can also be prepared by screening.

The seal 4 is deposited on one of the plates or on both of the plates 2 and 3, according to a path described below, i.e. along the four sides.

In a particular embodiment of FIG. 10, the organic seal 4 is located at the periphery of the surface common to the two front and rear plates 2 and 3. It is thus arranged on the periphery of the rear plate 3 except on the left side for the rear plate 3, to allow access from outside to external connecting conductors 12. For example, an external connecting conductor 12 of the end cells (1a and 1c) can be salient outwards beyond the seal 4.

The seal 4 can then be arranged, as described above, between the front plate 2 and rear plate 3, at the periphery of the module, so as to delineate a tight internal volume inside which all the cells 1 are arranged.

The seal 4 has a thickness of several hundred microns, which depends especially on the thickness of the cells 1, to which the thickness of the metal strips 11 forming interconnecting conductors, formed on the front face of the rear plate 3, connecting the cells 1 in series by connecting a positive pole of a cell 1a to a negative pole of the adjacent cell 1b, has to be added.

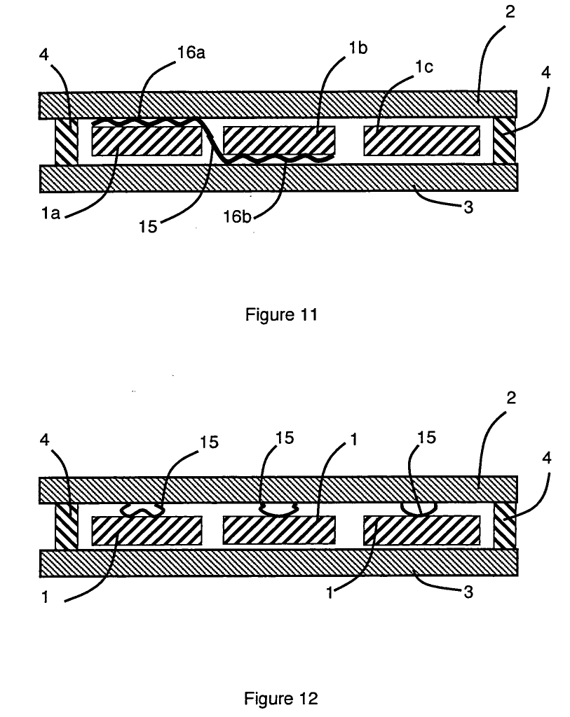

In FIG. 11, an interconnecting conductor 15 connects a front face of a first cell 1a and a rear face of an adjacent second cell 1b. The interconnecting conductor 15 is formed by a rigid material, for example by a copper and magnesium alloy or by a hardened copper, keeping all its electrical conductivity. A first undulating end 16a is arranged between the front face of the first cell 1a and the internal face of the front plate 2. A second undulating end 16b is arranged between the rear face of the second cell 1b and the internal face of the rear plate 3. In the particular embodiment represented in FIG. 12, the intermediate part of the interconnecting conductor, arranged between the adjacent cells 1a and 1b, is not undulating. In an alternative embodiment, one of the ends 16 can be achieved without undulation.

In like manner, an undulating interconnecting conductor 15 can be used to connect the positive and negative poles of two adjacent single-face cells, i.e. each having positive and negative poles arranged on the same side of the cell. This undulation enables the contact between the cell 1 and interconnecting conductor 15 to be improved by means of a spring effect.

Interconnecting conductors 15, formed by a rigid material, connecting the photovoltaic cells 1 to one another can have any profiled shape, for example a U-shaped, W-shaped or V-shaped cross-section, as represented in FIG. 12, so as to obtain a spring effect between the photovoltaic cells 1 and the corresponding plate 2 or 3. The spring effect enables variations of thickness of the cells and/or of the front and rear plates and variations due to thermal expansion of the elements constituting the module to be compensated, and thus enables the risk of breaking of the cells to be limited while ensuring a constant electrical contact between the cells 1 and the interconnecting conductors 15. The interconnecting conductors 15 can also be spiral-shaped.

The method according to the invention can be applied to production of photovoltaic modules, and then of solar generators, from square, rectangular or round photovoltaic cells the characteristic dimensions whereof can range from a few centimeters to several tens of centimeters. The cells are preferably square cells with sides having a dimension comprised between 8 cm and 30 cm.

The invention is not limited to the particular embodiments described and represented above. In particular, the strips of silver paste can be deposited on the internal face of the front plate. The invention applies to all types of photovoltaic cells, not only to silicon, monocrystalline or polycrystalline photovoltaic cells, but also to gallium arsenide cells, to cells formed by silicon strips, to silicon bead cells formed by a network of silicon beads inserted in conducting sheets, or to photovoltaic cells formed by deposition and etching of a thin film of silicon, of copper/indium/selenium or cadmium/tellurium on a glass or ceramic plate.

1. Method for production of a photovoltaic module comprising an assembly of photovoltaic cells arranged side by side between front and rear plates, and a seal arranged between the plates and delineating a tight internal volume which is kept at a pressure lower than atmospheric pressure, wherein the photovoltaic cells are arranged in the tight internal volume, and the seal is a flexible organic seal, the method comprising:
deposition of the organic seal, wherein
a negative pressure is formed by suction.

2. Method according to claim 1, successively comprising assembly of the module and, in a tight enclosure, sweeping by neutral gases, establishment of the negative pressure by suction and sealing of the front and rear plates by compression of the seal.

3. Method according to claim 1, successively comprising assembly and partial sealing of the module so as to leave two openings in the seal, sweeping by neutral gases of the internal volume by means of the two openings, establishment of the negative pressure by suction and closing of the openings.

4. Method according to claim 1, wherein the negative pressure inside the tight internal volume is formed, after sealing of the module, by suction by means of a perforating tool passing through the organic seal.

5. Method according to claim 1, comprising control of the atmosphere and of the gas composition inside the tight internal volume.

6. Method according to claim 1, comprising a compression step of the module designed to control the thickness of the module.

7. Method according to claim 1, wherein, before assembly of the plates, the photovoltaic cells and interconnecting conductors connecting the photovoltaic cells to one another are fixed onto one of the plates.

8. Method according to claim 7, wherein, before assembly, the photovoltaic cells and the interconnecting conductors are fixed onto one of the plates by means of a solvent-free organic glue.

9. Method according to claim 8, wherein the solvent-free organic glue comprises a derivative of the polyvinyl and polybutylene families.

10. Method according to claim 1, the front plate being made of glass, and method comprises, before assembly, a chemical treatment step of the glass front plate so as to make an internal face of the glass front plate rough.

11. Method according to claim 1, wherein, the photovoltaic cells each having positive and negative poles arranged on one and the same side of the cell, and method comprises, before the cells are fitted in place, deposition, on an internal face of one of the plates only, of at least one metal strip, connecting a positive pole of a cell to a negative pole of the adjacent cell so as to connect the cells in series.

12. Method according to claim 11, wherein the metal strip is formed by a strip of silver paste arranged on a zone connecting locations of two adjacent cells.
